(19) United States
(12) Patent Application Publication
(10) Pub. No.: US 2017/0040147 A1
(43) Pub. Date: Feb. 9, 2017

(54) Systems Comprising Silicon Coated Gas Supply Conduits and Methods for Applying Coatings

(71) Applicant: Lam Research Corporation, Fremont, CA (US)

(72) Inventors: Hong Shih, Walnut, CA (US); John Michael Kerns, Livermore, CA (US); Yan Fang, Fremont, CA (US); Allan Ronne, Santa Clara, CA (US)

(73) Assignee: Lam Research Corporation, Fremont, CA (US)

(21) Appl. No.: 15/232,214

(22) Filed: Aug. 9, 2016

Related U.S. Application Data
(62) Division of application No. 13/286,637, filed on Nov. 1, 2011, now abandoned.

(51) Int. Cl. H01J 37/32; B23K 31/02; C23C 22/50; C23C 30/00; C25F 3/24

(52) U.S. Cl. CPC H01J 37/32495; H01J 37/3244; C23C 30/00; C25F 3/24; C23C 22/50; B23K 31/02; H01J 2237/334; B23K 2201/35

(57) ABSTRACT

In one embodiment, a plasma etching system may include a process gas source, a plasma processing chamber, and a gas supply conduit. A plasma can be formed from a process gas recipe in the plasma processing chamber. The gas supply conduit may include a corrosion resistant layered structure forming an inner recipe contacting surface and an outer environment contacting surface. The corrosion resistant layered structure may include a protective silicon layer, a passivated coupling layer and a stainless steel layer. The inner recipe contacting surface can be formed by the protective silicon layer. The passivated coupling layer can be disposed between the protective silicon layer and the stainless steel layer. The passivated coupling layer can include chrome oxide and iron oxide. The chrome oxide can be more abundant in the passivated coupling layer than the iron oxide.

### CROSS-REFERENCE TO RELATED APPLICATION

This application is a divisional application of U.S. patent application Ser. No. 13/286,637, filed Nov. 1, 2011, the entire contents of which is hereby incorporated by reference.

### SUMMARY

The present disclosure relates generally to gas supply conduits comprising a protective silicon layer and, more particularly, to plasma etching systems comprising gas supply conduits comprising a protective silicon layer and methods for applying a protective silicon layer to gas supply conduits. Although the context of the present disclosure is not limited to particular types of plasma systems for the production of semiconductor devices, for the purposes of illustration, plasma etching systems commonly produce a plasma by subjecting process gases to a relatively high frequency electric field (e.g., about 13.56 MHz). The plasma is commonly contained within a plasma processing chamber that encloses a volume of space substantially maintained at a vacuum, i.e., air may be evacuated from the plasma processing chamber with a vacuum pumping system to maintain a pressure much less than atmospheric pressure. A semiconductor or glass substrate such as, for example, a wafer comprising silicon, can be placed within the plasma processing chamber and subjected to the plasma to transform the substrate into desired device.

FIG. 1 illustrates a plasma etching system 100 comprising a process gas source 102 in fluid communication with a plasma processing chamber 104 via a gas supply conduit 106. For example, the process gas source 102 may provide a process gas to the plasma processing chamber 104. Further teachings regarding the structure of a plasma etching system 100 similar to that illustrated in FIGS. 1 can be found in US Pub. No. 2011/0056626, pertinent portions of which are incorporated herein by reference.

The process gas may include a halogen gas and may erode the gas supply conduit 106. Those practicing the embodiments described herein may find favorable utility in reducing the deleterious impact of process gases upon a variety of types of gas supply conduits for a variety of types of plasma etching systems.

In one embodiment, a plasma etching system may include a process gas source, a plasma processing chamber, and a gas supply conduit. The process gas source can be in fluid communication with the gas supply conduit. The gas supply conduit can be in fluid communication with the plasma processing chamber. A process gas recipe can be conveyed via the gas supply conduit, such that the process gas recipe is conveyed from the process gas source to the plasma processing chamber. A plasma for etching a device can be formed from the process gas recipe in the plasma processing chamber. The gas supply conduit may include a corrosion resistant layered structure forming an inner recipe contacting surface and an outer environment contacting surface. The corrosion resistant layered structure may include a protective silicon layer, a passivated coupling layer and a stainless steel layer. The inner recipe contacting surface can be formed by the protective silicon layer. The passivated coupling layer can be disposed between the protective silicon layer and the stainless steel layer. The passivated coupling layer can include chrome oxide and iron oxide. The chrome oxide can be more abundant in the passivated coupling layer than the iron oxide.

In another embodiment, a method for applying a coating may include providing a gas supply conduit comprising stainless steel. The gas supply conduit can be electropolished to yield a electropolished gas supply conduit. A passivation solution can be applied to the electropolished gas supply conduit to yield a passivated gas supply conduit. The passivated gas supply conduit may include a passivated coupling layer. The passivation solution may include nitric acid. A protective silicon layer can be applied to the passivated coupling layer of the passivated gas supply conduit. The passivated coupling layer may include chrome oxide and iron oxide. The chrome oxide can be more abundant in the passivated coupling layer than the iron oxide.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a plasma etching system according to one or more embodiments shown and described herein;

FIG. 2 schematically depicts a gas supply conduit according to one or more embodiments shown and described herein;

FIG. 3 schematically depicts a cross sectional view of a gas supply conduit according to one or more embodiments shown and described herein; and

FIG. 4 schematically depicts a cut away view of an injector block according to one or more embodiments shown and described herein.

### DETAILED DESCRIPTION

As is noted above, the present disclosure relates gas supply conduits comprising a protective silicon layer. The gas supply conduits may be utilized in a plasma etching system to transport process gases such as, for example, during plasma etching or deposition operations. The concepts of the present disclosure should not be limited to plasma etching systems. Thus, the gas supply conduits described herein may be utilized in a variety of semiconductor fabrication systems or other gas delivery systems for the transport of gases similar to the process gas recipes described herein.

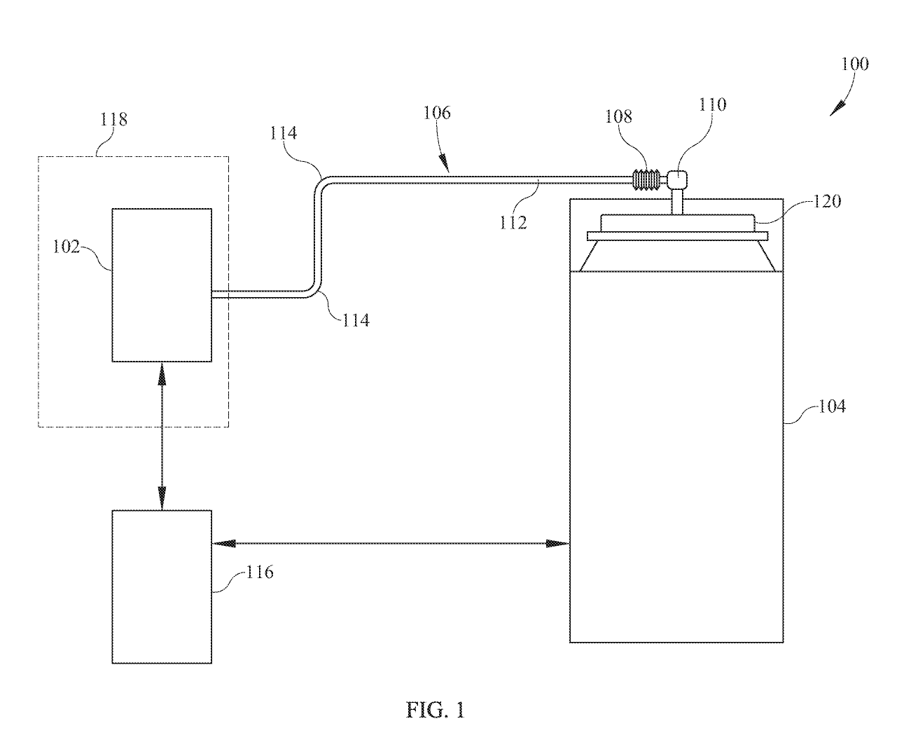

Referring to FIG. 1, a plasma etching system 100 comprises a process gas source 102, a plasma processing chamber 104, and a gas supply conduit 106.

The process gas source 102 is in fluid communication with the gas supply conduit 106. The gas supply conduit 106 is in fluid communication with the plasma processing chamber 104. Accordingly, a process gas recipe can be conveyed via the gas supply conduit 106, i.e., the process gas recipe can be conveyed from the process gas source 102 to the plasma processing chamber 104. For the purpose defining and describing the present disclosure, it is noted that the phrase “fluid communication,” as used herein, means the exchange of fluid from one object to another object, which may include, for example, the flow of compressible and incompressible fluids.

The process gas source 102 provides process gases for the plasma etching system 100. Specifically, the process gas recipe may require a plurality of process gases. The process gases may comprise halogens or halogen elements such as, for example, fluorine (F), chlorine (Cl), bromine (Br), iodine (I), and astatine (At). Moreover, specific process gases may include CClF₃, C4F₈, C4F₆, CHF₃, CH₂F₃, CF₄, HBr, CH₃F, C₂F₄, N₂, O₂, Ar, Xe, He, H₂, NH₃, SF₆, BCl₃, Cl₂, and other equivalent plasma processing gases. Accordingly, the process gas source 102 may include a plurality of process gases stored in pressure vessels such as, for example compressed gas cylinders. The process gas source may further include distribution and control components such as, for example, mass flow controllers, pressure transducers, pressure regulators, heaters, filters, purifiers, manifolds, and shutoff valves. As is noted above, the process gases may include hazardous gases. Accordingly, the process gas source 102 may be fully or partially enclosed within the plasma processing chamber 104. Additionally or alternatively, the process gas source 102 may be enclosed within a containment enclosure 118, which may be coupled to the exterior of the plasma processing chamber 104.

The plasma processing chamber 104 is an environmentally controlled enclosure for processing a desired substrate with a plasma. The plasma processing chamber 104 may comprise and may enclose a plasma generating assembly 120 in fluid communication with the gas supply conduit 106. Plasma generating assembly 120 may include an RF source for generating an electromagnetic field that is separated from the plasma by a dielectric window. The plasma generating assembly 120 may further comprise an upper electrode and a lower electrode for directing a plasma generated by the electromagnetic field and the process gas recipe towards a substrate material. For example, the upper electrode may be provided with a plurality of holes for the dispersion of process gases throughout the plasma processing chamber 104. The upper electrode and the lower electrode can operate as an anode and a cathode (respectively or vice versa) for orienting the electric field and directing the plasma towards the substrate. Accordingly, the plasma may be utilized etch the substrate according to the process gas recipe.

The plasma etching system 100 may further comprise a process controller 116 communicably coupled to the process gas source 102 and the plasma processing chamber 104. The process controller 116 comprises an electronic processor communicably coupled to memory. The process controller is configured to execute machine readable instructions stored on the memory to control the plasma processing of a substrate. Accordingly, the process controller 116 can control parameters such as process gas recipe (gas flow mix, gas flow rate, pressure, etc.) and plasma processing chamber 104 parameters (voltage, temperature, pressure, gas mixture, etc.).

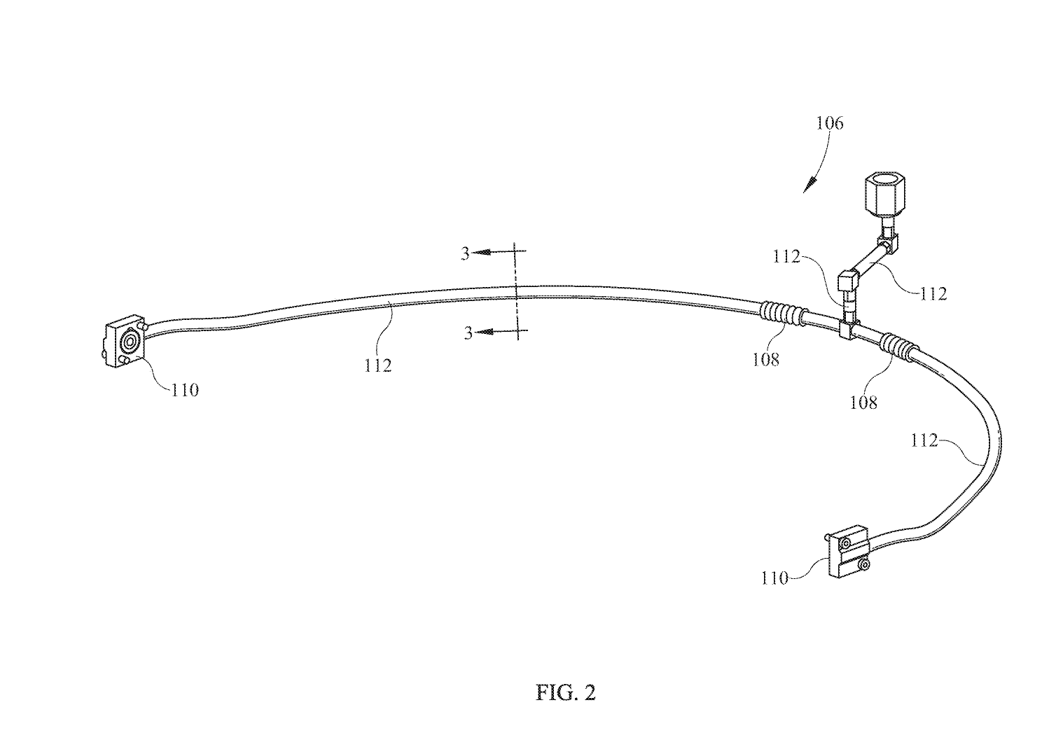

Referring collectively to FIGS. 1 and 2, the gas supply conduit 106 for conveying process gases from the process gas source 102 to the plasma processing chamber 104 is schematically depicted. The gas supply conduit 106 may comprise corrugated bellows 108, injector blocks 110, tube portions 112, and microfits 114 joined together and configured to provide a fluidic path for process gases. For example, a portion of the gas supply conduit 106 may be shaped to conform to the outer dimensions of the plasma processing chamber 104.

The corrugated bellows 108 is formed with furrows and ridges to allow the gas supply conduit 106 to flex (e.g., during processing, assembly, disassembly, etc.). The corrugated bellows 108 is a hollow member that that may at least partially enclose an interior volume from the exterior of the corrugated bellows 108. The corrugated bellows 108 can be substantially cylindrically shaped such that the interior volume is demarcated by the furrows and ridges of the corrugated bellows 108. In some embodiments, the corrugated bellows 108 may be bound to restrict the flexibility of the corrugated bellows. The motion of the corrugated bellows 108 may be limited to such that corrugated bellows 108 bends less than about ±10° such as, for example, about ±3° or about ±1.5°.

The injector blocks 110 are configured to couple the gas supply conduit 106 with the plasma processing chamber 104 such that the process gases may flow from the gas supply conduit 106 into the plasma processing chamber 104. The injector blocks 110 may be substantially box shaped and may be fastened to the plasma processing chamber with a fastener (e.g., a bolt).

The tube portions 112 are substantially cylindrically shaped hollow members configured to transport process gases within an enclosed cavity. The tube portions 112 may be substantially straight or may be contoured to any desired shape. The microfits 114 are hollow fittings with multiple inlets that are configured to alter the direction of the gas supply conduit 106. For example, the microfit 114 may be a substantially L-shaped body for abruptly turning the gas supply conduit 106 about 90°, a substantially V-shaped body for abruptly turning the gas supply conduit 106 about 45°, or a substantially T-shaped body for abruptly turning the gas supply conduit 106 about 90° and providing an inlet substantially in line with another inlet. It is noted that, while FIG. 2 depicts the microfits 114 as L-shaped or T-shaped, the microfits 114 may have any number of inlets oriented at any angle with respect to one another such that the gas supply conduit 106 is capable of delivering the process gases to the plasma processing chamber 104 according to a process gas recipe.

Accordingly, the gas supply conduit 106 can be formed by fusing any number of corrugated bellows 108, injector blocks 110, tube portions 112, and microfits 114 to form the desired gas flow path. For example, the process gas source 102 may be fully or partially disposed within the plasma processing chamber 104. Thus, the gas supply conduit 106 may travel from the process gas source 102 out to the exterior of the plasma processing chamber 104 to supply process gas to the interior of the plasma processing chamber 104. For example, the gas supply conduit 106 may include an injector block 110 in fluid communication with the interior of the plasma processing chamber 104.

Any number of corrugated bellows 108, injector blocks 110, tube portions 112, and microfits 114 can be fused with one another such that the leakage of process gases from the gas supply conduit 106 is substantially minimized. Suitable fusion methods include welding, brazing, or any other method capable of substantially sealing the process gases within the gas supply conduit 106 and providing a sufficient mechanical bond for stability during operation of the plasma etching system 100. For example, when the gas supply conduit 106 comprises materials of similar compositions and melting points, the gas supply conduit 106 may be fusion welded to coalesce the constituents of the gas supply conduit 106. Fusion welding may, due to the relatively high processing temperatures, generate a heat-affected zone in the material at and adjacent to the welded joint. Suitable welding processes include arc welding, oxy-fuel welding, electric resistance welding, laser beam welding, electron beam welding, thermite welding, or any other welding process capable of substantially sealing the process gases within the gas supply conduit 106.

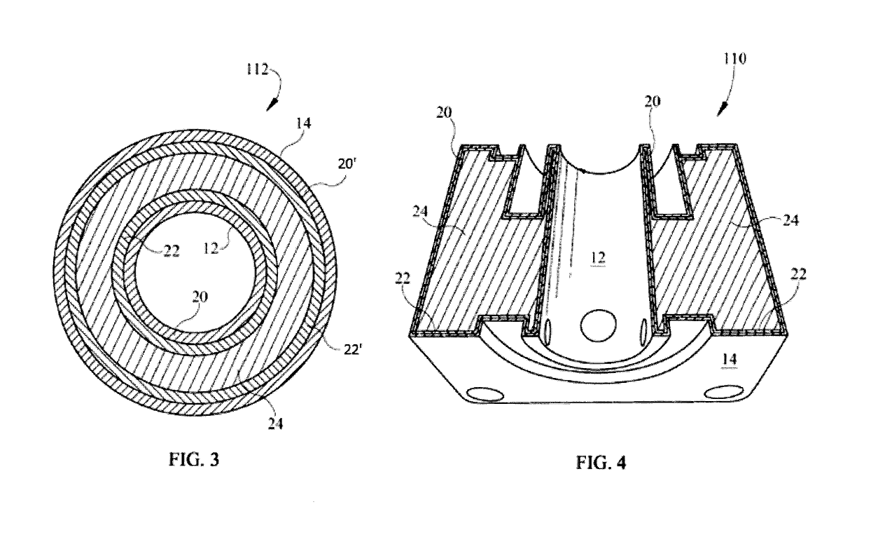

Any portion of the gas supply conduit 106 can include a corrosion resistant layered structure. Referring collectively to FIGS. 3 and 4, the corrosion resistant layered structure forms an inner recipe contacting surface 12 for enclosing process gasses and an outer environment contacting surface 14 for interacting with the environment surrounding the gas supply conduit 106 (FIGS. 1 and 2). It is noted that the tube portion 112 (FIG. 3) and the injector block 110 (FIG. 4) are depicted for clarity and not to limit the embodiments described herein to any specific portion of the gas supply conduit 106 (FIGS. 1 and 2).

The corrosion resistant layered structure comprises a protective silicon layer 20, a passivated coupling layer 22 and a stainless steel layer 24. The inner recipe contacting surface 12 is formed by the protective silicon layer 20 and the passivated coupling layer 22 is disposed between the protective silicon layer 20 and the stainless steel layer 24. The corrosion resistant layered structure may optionally include a second protective silicon layer 20′ and a second passivated coupling layer 22′. Specifically, a stainless steel layer 24 may be disposed between two passivated coupling layers 22,22′. A protective silicon layer 20,20′ may be coupled to each passivated coupling layer 22,22′ such that a protective silicon layer 20 forms the inner recipe contacting surface 12 and a protective silicon layer 20′ forms the outer environment contacting surface 14. The protective silicon layer 20,20′ may be less than about 1 micrometer thick such as, for example, less than about 0.85 micrometers, from about 0.02 micrometers to about 0.8 micrometers, or from about 0.04 micrometers to about 0.77 micrometers.

The stainless steel layer 24 is formed from any alloy type, grade or surface finish of stainless steel suitable to endure exposure to the process gases described herein such as, for example, stainless steel types covered under ASTM A-967. Suitable stainless steel alloys may comprise molybdenum, titanium, austenitic chromium-nickel-manganese alloys, austenitic chromium-nickel-manganese alloys, austenitic chromium-nickel alloys, ferritic chromium alloys, martensitic chromium alloys, heat-resisting chromium alloys, or martensitic precipitation hardening alloys. The stainless steel may be subjected to vacuum induction melting (VIM) to provide relatively tight compositional limits and relatively low gas contents for subsequent remelting. The stainless steel may be subjected to vacuum arc remelting (VAR) to produce a relatively high quality ingot with low levels of volatile tramp elements and reduced gas levels. Some preferred stainless steels for use in the stainless steel layer 24 include 316 stainless steel, 316L stainless steel, and 316L VIM/VAR stainless steel.

The passivated coupling layer 22 is a hardened non-reactive film that comprises chrome oxide and iron oxide, such that the chrome oxide is more abundant in the passivated coupling layer 22 than the iron oxide. In some embodiments, the chrome oxide to iron oxide ratio will be greater than about 2 in the passivated coupling layer 22. Unexpectedly, the passivated coupling layer 22 may improve adhesion of the protective silicon layer 20 to the stainless steel layer 24, particularly in heat affected zones and the corrugated bellows 108 (FIGS. 2 and 3). Moreover, it has been discovered that the passivated coupling layer 22 demonstrates improved resistance to the deleterious effects of the process gases to the stainless steel layer 24, particularly in heat affected zones and the corrugated bellows 108 (FIGS. 2 and 3). The passivated coupling layer 22 may be less than about 1 micrometer thick such as, for example, less than about 0.5 micrometers, less than about 10 nanometers, or less than about 5 nanometers. It is noted that the term “layer,” as used herein, means a substantially continuous thickness of material, which may include layer defects, disposed upon another material. Layer defects may include cracks, voids, peeling, inclusions of impurities or excess layer material, pitting, mars nicks, or other manufacturing, surface or material defects. Accordingly, while FIGS. 3 and 4 depict idealized layers, any of the layers described herein may include layer defects or any other defect without departing from scope of the present disclosure. Moreover, it is noted that layer thicknesses may be determined with X-ray photoelectron spectroscopy (XPS) or any other substantial equivalent for measured layer thicknesses.

Referring collectively to FIGS. 2 and 3, the corrosion resistant layered structures described herein may be formed by electropolishing the stainless steel layer 24 prior to coating the stainless steel layer 24 with further layers of material. For example, gas supply conduit 106 may be initially formed by welding a variety of stainless steel components (e.g., corrugated bellows 108, injector block 110, tube portion 112, and microfit 114). The gas supply conduit 106 can be electropolished by subjecting the gas supply conduit 106 to an electrochemical process to remove removes material and form a relatively smooth surface finish. In some embodiments, the electropolished gas supply conduit may have a surface roughness Ra (arithmetic mean) of less than about 20 micro-inches such as less than about 10 micro-inches.

The stainless steel layer 24 may be passivated following electropolishing, or in some embodiments, the stainless steel layer may be passivated without prior electropolishing. Specifically, the electropolished gas supply conduit may be subjected to a passivation solution to yield a passivated gas supply conduit comprising a passivated coupling layer 22. The passivation solution comprises nitric acid. The passivation solution may include less than about 50 volume percent of nitric acid such as, for example, from about 30 volume percent of nitric acid to about 40 volume percent of nitric acid. In some embodiments, the passivation solution may be applied for more than about 60 minutes such as, for example, from about 117 minutes to about 123 minutes, or about 120 minutes.

The protective silicon layer 20 may be applied or deposited onto the passivated coupling layer 22. Suitable methods for applying the protective silicon layer 20 are described in U.S. Pat. Nos. 6,444,326, 6,511,760 and 7,070,833, the pertinent portions of which are incorporated by reference herein, which are assigned to Silcotek Corporation of Bellefonte, Pa., USA.

For the purposes of describing and defining the present disclosure it is noted that the terms “substantially” and “about” are utilized herein to represent the inherent degree of uncertainty that may be attributed to any quantitative comparison, value, measurement, or other representation. The terms “substantially” and “about” are also utilized herein to represent the degree by which a quantitative representation may vary from a stated reference without resulting in a change in the basic function of the subject matter at issue.

It is noted that the term “commonly,” when utilized herein, is not utilized to limit the scope of the claims or to imply that certain features are critical, essential, or even important to the structure or function of the claims. Rather, these terms are merely intended to identify particular aspects of an embodiment of the present disclosure or to emphasize alternative or additional features that may or may not be utilized in a particular embodiment of the present disclosure. Similarly, although some aspects of the present disclosure are identified herein as preferred or particularly advantageous, it is contemplated that the present disclosure is not necessarily limited to these preferred aspects of the disclosure.

Having described the invention in detail and by reference to specific embodiments thereof, it will be apparent that modifications and variations are possible without departing from the scope of the invention defined in the appended claims.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

1-13. (canceled)

14. A method for applying a coating, the method comprising:
electropolishing an inner surface of a stainless steel gas supply conduit to yield a electropolished inner surface of the gas supply conduit;
applying a passivation solution to the electropolished inner surface to deposit a passivated coupling layer, wherein the passivation solution comprises nitric acid; and
applying a protective silicon layer to the passivated coupling layer, wherein the passivated coupling layer comprises chrome oxide and iron oxide, such that the chrome oxide is more abundant in the passivated coupling layer than the iron oxide.

15. The method of claim 14, further comprising welding the gas supply conduit, wherein the gas supply conduit comprises a microfit, a corrugated bellows and an injector block.

16. The method of claim 14, wherein the gas supply conduit comprises 316L stainless steel, 316L VIM/VAR stainless steel, or both.

17. The method of claim 14, wherein the electropolished inner surface of the gas supply conduit has a surface roughness Ra of less than about 20 micro-inches.

18. The method of claim 14, wherein the passivation solution comprises less than about 50 volume percent of the nitric acid.

19. The method of claim 14, wherein the passivation solution is applied for longer than about 60 minutes.

20. The method of claim 14, wherein a ratio of the chrome oxide to the iron oxide is greater than about 2 in the passivated coupling layer and the protective silicon layer is less than about 1 micrometer thick.

21. The method of claim 14, wherein the protective silicon layer has a thickness of less than 1 micron.

22. The method of claim 14, wherein the protective silicon layer has a thickness of less than 0.85 micron.

23. The method of claim 14, wherein a ratio of the chrome oxide to the iron oxide in the passivated coupling layer is greater than about 2.

24. The method of claim 14, wherein the stainless steel is 316L stainless steel.

25. The method of claim 14, wherein the stainless steel is 316L VIM/VAR stainless steel.

26. The method of claim 14, wherein the gas supply conduit comprises a corrugated bellows.

27. The method of claim 14, wherein the gas supply conduit comprises a heat affected zone of a weld.

28. The method of claim 14, wherein the gas supply conduit comprises an injector block.

29. The method of claim 14, the gas supply conduit comprises a microfit.

30. The method of claim 14, further comprising electropolishing an outer surface of the gas supply conduit to yield an electropolished outer surface of the gas supply conduit;
applying a passivation solution to the electropolished outer surface to deposit an outer passivated coupling layer, wherein the passivation solution comprises nitric acid; and
applying a protective silicon layer to the outer passivated coupling layer, wherein the outer passivated coupling layer comprises chrome oxide and iron oxide, such that the chrome oxide is more abundant in the outer passivated coupling layer than the iron oxide.
